(19) United States
(12) Patent Application Publication
(10) Pub. No.: US 2015/0075944 A1
(43) Pub. Date: Mar. 19, 2015

(54) SCROLL WHEEL FOR TRANSFERRING GLASS SUBSTRATE

(71) Applicant: Shenzhen China Star Optoelectronics Technology Co. Ltd., Shenzhen (CN)

(72) Inventors: Zhenhua Guo, Shenzhen (CN); Xhun Hao Wu, Shenzhen (CN); Kun Hsien Lin, Shenzhen (CN); Yunshao Jiang, Shenzhen (CN); Yongqiang Wang, Shenzhen (CN); Xiande Li, Shenzhen (CN); Weibing Yang, Shenzhen (CN); Minghu Qi, Shenzhen (CN); Zhenhong Chen, Shenzhen (CN); Zhiyou Shu, Shenzhen (CN)

(21) Appl. No.: 13/636,705

(22) PCT Filed: Jun. 7, 2012
(86) PCT No.: PCT/CN12/76587

§ 371 Date: Sep. 24, 2012

(30) Foreign Application Priority Data
May 31, 2012 (CN) 201210175195.4

(51) Int. Cl. B65G 39/07; B65G 49/06; H01L 21/677; B65G 39/06

(52) U.S. Cl. CPC B65G 39/07; B65G 39/06; B65G 49/064; H01L 21/67706
USPC 193/37

(57) ABSTRACT

The present invention provides a scroll wheel for transferring a glass substrate, which comprises a rolling body and a surrounding member. The rolling body has an outward-curving peripheral surface, and an outermost circumference on the surface of the rolling body has an groove disposed around. The rolling body rotates on a central axis. The surrounding member is engaged with the groove of the rolling body. The surrounding member is in contact with the glass substrate and is used to support and transfer the glass substrate. The present invention can prevent the glass substrate from being scratched in the transferring process and reduce the damage of the glass substrate. Moreover, the present invention can make the best use of an element of the scroll wheel that is reusable and reduce the cost.

### BACKGROUND OF THE INVENTION

1. Field of the Invention

The present invention relates to a liquid crystal display manufacture technology, and more particularly, to a scroll wheel used for transferring a glass substrate.

2. Description of Prior Art

A scroll wheel is required in a traditional process for manufacturing liquid crystal display panels. The scroll wheel is used to transfer a glass substrate. Conventionally, a part of the scroll wheel that is in contact with the glass substrate is not smooth enough and its hardness is high. This may make a scratch on the glass substrate in the transferring process, and thus degrade the completeness of the glass substrate.

Please refer to FIG. 1, which is a normal axomometric diagram showing a conventional scroll wheel 101. The scroll wheel 101 has to support and transfer the glass substrate. Accordingly, the outward-curving surface of the scroll wheel 101 is required to be smooth and clean. When the smoothness and clearness of the outward-curving surface of the scroll wheel 101 does not meet a certain requirement, the scroll wheel 101 may make a scratch on the glass substrate during the process of transferring the glass substrate.

It has to replace the entire wheel 101 when a part of the scroll wheel 101, e.g., an outermost circumference on the surface of the scroll wheel 101, that is in contact with the glass substrate is worn out. It is quite inconvenient to replace the whole wheel 101 and this may consume a great deal of human and non-human resources. Actually, it is a waste to replace entire wheel 101 for the sake of abrasion of the part of scroll wheel 101.

### SUMMARY OF THE INVENTION

An object of the present invention is to provide a scroll wheel for transferring a glass substrate, which can prevent the glass substrate from being scratched in the transferring process, reduce the damage of the glass substrate, make the best use of an element of the scroll wheel that is reusable, and reduce the cost.

To solve the above problems, the present invention provides a scroll wheel for transferring a glass substrate, comprising: a rolling body having an outward-curving peripheral surface, an outermost circumference on the surface of the rolling body has an groove disposed around, the rolling body rotates on a central axis; and a surrounding member engaged with the groove of the rolling body, the surrounding member is in contact with the glass substrate and is used to support and transfer the glass substrate, wherein the surrounding member has a main portion and a protrusion, the protrusion is formed by extending the main portion along a first direction; the first direction is a direction from a center of the rolling body to a center of a cross section of the groove along a radial direction; and the main portion of the surrounding member has a cross section that is shaped substantially as the same as that of the groove.

In the aforesaid scroll wheel for transferring the glass substrate, the surrounding member has a height greater than a depth of the groove in a cross-sectional view.

In the aforesaid scroll wheel for transferring the glass substrate, the height is equal to a projected length of the cross section of the surrounding member along the first direction.

In the aforesaid scroll wheel for transferring the glass substrate, the depth is equal to a projected length of the cross section of the groove along the first direction.

In the aforesaid scroll wheel for transferring the glass substrate, a hardness number of the surrounding member is lower than that of the glass substrate.

Another object of the present invention is to provide a scroll wheel for transferring a glass substrate, which can prevent the glass substrate from being scratched in the transferring process, reduce the damage of the glass substrate, make the best use of an element of the scroll wheel that is reusable, and reduce the cost.

To solve the above problems, the present invention provides a scroll wheel for transferring a glass substrate, comprising: a rolling body having an outward-curving peripheral surface, an outermost circumference on the surface of the rolling body has an groove disposed around, the rolling body rotates on a central axis; and a surrounding member engaged with the groove of the rolling body, the surrounding member is in contact with the glass substrate and is used to support and transfer the glass substrate.

In the aforesaid scroll wheel for transferring the glass substrate, the surrounding member has a main portion and a protrusion, and the protrusion is formed by extending the main portion along a first direction.

In the aforesaid scroll wheel for transferring the glass substrate, the first direction is a direction from a center of the rolling body to a center of a cross section of the groove along a radial direction.

In the aforesaid scroll wheel for transferring the glass substrate, the surrounding member has a height greater than a depth of the groove in a cross-sectional view.

In the aforesaid scroll wheel for transferring the glass substrate, the depth is equal to a projected length of the cross section of the groove along the first direction.

In the aforesaid scroll wheel for transferring the glass substrate, the depth is equal to a projected length of the cross section of the groove along the first direction.

In the aforesaid scroll wheel for transferring the glass substrate, the first direction is a direction from a center of the rolling body to a center of gravity of a cross section of the groove along a radial direction.

In the aforesaid scroll wheel for transferring the glass substrate, the surrounding member has a height greater than a depth of the groove in a cross-sectional view.

In the aforesaid scroll wheel for transferring the glass substrate, the depth is equal to a projected length of the cross section of the groove along the first direction.

In the aforesaid scroll wheel for transferring the glass substrate, the depth is equal to a projected length of the cross section of the groove along the first direction.

In the aforesaid scroll wheel for transferring the glass substrate, the main portion of the surrounding member has a cross section that is shaped substantially as the same as that of the groove.

In the aforesaid scroll wheel for transferring the glass substrate, a hardness number of the surrounding member is lower than that of the glass substrate.

In the aforesaid scroll wheel for transferring the glass substrate, the surrounding member is made of rubber.

In the aforesaid scroll wheel for transferring the glass substrate, the surrounding member is made of plastic.

Compared to conventional skills, the scroll wheel of the present invention comprises the rolling body and the surrounding member that are engaged with each other. Accordingly, it only needs to replace the surrounding member rather than replacing the whole wheel when the wheel needs to be maintained or repaired. The rolling body of the present invention can be reused. Therefore, the technical scheme provided in the present invention can reduce the cost. Moreover, the protrusion of the surrounding member that is used to directly in contact with the glass substrate is made of a material with a hardness number lower than that of the glass substrate material. As a result, the scroll wheel will not make a scratch on the glass substrate during the process of using the scroll wheel to transfer the glass substrate. This reduces the damage of the glass substrate.

To make above content of the present invention more easily understood, it will be described in details by using preferred embodiments in conjunction with the appending drawings.

### BRIEF DESCRIPTION OF THE DRAWINGS

FIG. 1 is a normal axomometric diagram showing a conventional scroll wheel.

FIG. 2 is a front view of a scroll wheel according to a first embodiment of the present invention.

FIG. 3 is a front view of a rolling body shown in FIG. 2.

FIG. 4 is a diagram showing a cross section made along A-A′ in FIG. 2.

FIG. 5 is a front view of a scroll wheel according to a second embodiment of the present invention.

FIG. 6 is a front view of a rolling body shown in FIG. 5.

FIG. 7 is a diagram showing a cross section made along B-B′ in FIG. 5.

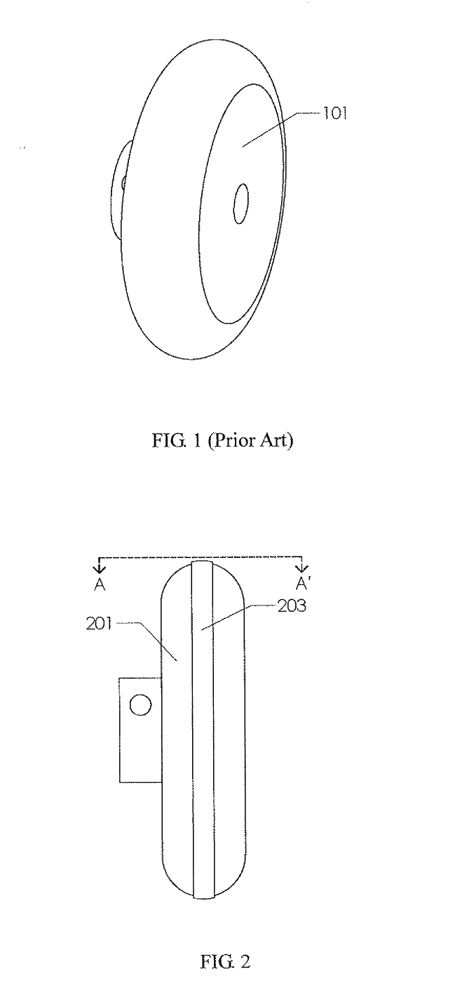

### DETAILED DESCRIPTION OF THE PREFERRED EMBODIMENTS

The following descriptions for the respective embodiments are specific embodiments capable of being implemented for illustrations of the present invention with referring to appended figures.

Please refer to FIG. 2, which is a front view of a scroll wheel according to a first embodiment of the present invention. In the present embodiment, the scroll wheel used to transfer a glass substrate comprises a rolling body 201 and a surrounding member 203. The rolling body 201 has an outward-curving peripheral surface. The surrounding member 203 and the rolling body 201 are assembled together. Specifically, the surrounding member 203 is engaged with the rolling body 201 at an outermost circumference of the outward-curving peripheral surface. A hardness number of the surrounding member 203 is lower than that of the glass substrate. The surrounding member 203 may be made of rubber or plastic. In the present embodiment, the scroll wheel has the surrounding member 203 arranged at the outermost circumference thereof. That is to say a material having a hardness number lower than that of the glass substrate material is used to contact with the glass substrate. In such a manner, the scroll wheel of the present invention will not make a scratch on the glass substrate during transferring the glass substrate. Moreover, the surrounding member 203 is replaceable. In the present invention, the surrounding member 203 can be detached from the rolling body 201 when the surrounding member 203 is required to be refreshed. Compared to conventional skills, the present invention has not to replace the rolling body 201 all the time. Therefore, the rolling body 201 can be reused and the cost is reduced for this reason.

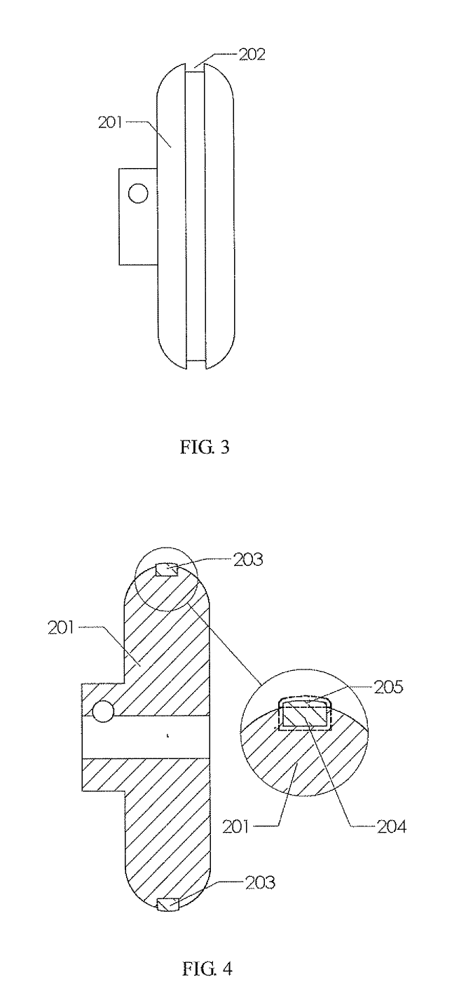

Please refer to FIG. 3, which is a front view of a rolling body shown in FIG. 2. In the present embodiment, the rolling body 201 has a groove 202, which is arranged at the outermost circumference of the outward-curving peripheral surface of the rolling body 201. A cross section of the groove 202 has a regular shape, e.g., a rectangle. The shape of the cross section is made by four vertices on the cross-sectional area of the groove 202. That is, the rectangle is formed by connecting the four vertices of the groove 202. The groove 202 has a depth and the depth is equal to a projected length of the cross section of the groove 202 along a first direction. The first direction is a direction from a center of the rolling body 201 to a center or a center of gravity of the cross section of the groove 202 along a radial direction.

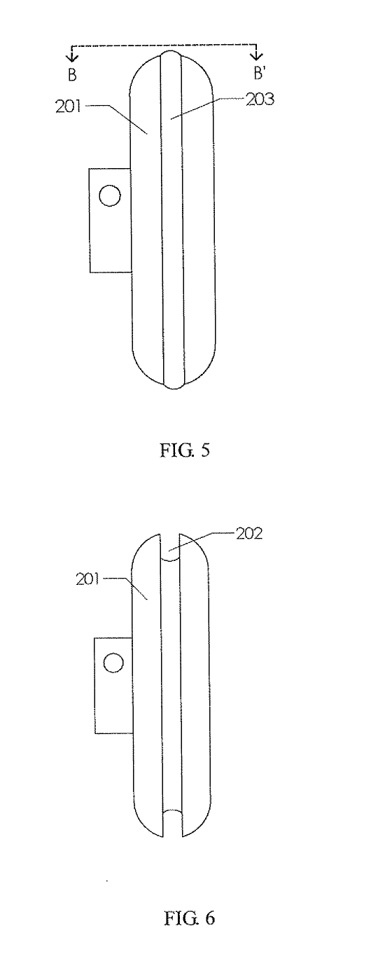

Please refer to FIG. 4, which is a diagram showing a cross section made along A-A′ in FIG. 2. In the present embodiment, the surrounding member 203 has a main portion 204 and a protrusion 205. The protrusion 205 is formed by extending the main portion 204 along the first direction. The first direction is a direction from a center of the rolling body 201 to a center or a center of gravity of the cross section of the groove 202 along a radial direction. The surrounding member 203 has a height and the height is equal to a projected length of the cross section of the surrounding member 203 along the first direction. In the present embodiment, the main portion 204 of the surrounding member 203 has a cross section that is shaped substantially as the same as that of the groove 202 of the rolling body 201. The height of the surrounding member 203 is greater than the depth of the groove 202 in the cross-sectional view. Therefore, the protrusion 205 of the surrounding member 203 can protrude from the outward-curving peripheral surface of the rolling body 201 when the surrounding member 203 and the rolling body 201 are engaged with each other. In the present embodiment, the protrusion 205 and the main body 204 of the surrounding member 203 may be made of the same material. Alternatively, the protrusion 205 and the main body 204 may be made of the different materials. In the process of using the scroll wheel of the present invention to transfer the glass substrate, the protrusion 205 is in contact with the glass substrate and is able to be used to support and transfer the glass substrate. Since the hardness number of the surrounding member 203 of the present invention is lower than that of the glass substrate, the protrusion 205 that directly touches the glass substrate will not make a scratch on the glass substrate.

In the present embodiment, there also has a fastening member (not shown) disposed at the groove 202 of the rolling body 201. Specifically, the fastening member is disposed on an inner wall of the groove 202. The fastening member may be a convex portion and the surrounding member 203 has a concave portion disposed at a position corresponding to the convex portion. The convex portion and the concave portion are engaged with each other. Alternatively, the fastening member may be a concave portion and the surrounding member 203 has a convex portion disposed at a position corresponding to the concave portion. The concave portion and the convex portion are engaged with each other.

Please refer to FIG. 5, which is a front view of a scroll wheel according to a second embodiment of the present invention. In the present embodiment, the scroll wheel used to transfer a glass substrate comprises a rolling body 201 and a surrounding member 203. The rolling body 201 has an outward-curving peripheral surface. The surrounding member 203 and the rolling body 201 are assembled together. Specifically, the surrounding member 203 is engaged with the rolling body 201 at an outermost circumference of the outward-curving peripheral surface. A hardness number of the surrounding member 203 is lower than that of the glass substrate. The surrounding member 203 may be made of rubber or plastic. In the present embodiment, the scroll wheel has the surrounding member 203 arranged at the outermost circumference thereof. That is to say a material having a hardness number lower than that of the glass substrate material is used to contact with the glass substrate. In such a manner, the scroll wheel of the present invention will not make a scratch on the glass substrate during transferring the glass substrate. Moreover, the surrounding member 203 is replaceable. In the present invention, the surrounding member 203 can be detached from the rolling body 201 when the surrounding member 203 is required to be refreshed. Compared to conventional skills, the present invention has not to replace the rolling body 201 all the time. Therefore, the rolling body 201 can be reused and the cost is reduced for this reason.

Please refer to FIG. 6, which is a front view of a rolling body shown in FIG. 5. In the present embodiment, the rolling body 201 has a groove 202, which is arranged at the outermost circumference of the outward-curving peripheral surface of the rolling body 201. A cross section of the groove 202 has an irregular shape. The shape of the cross section is made by joining a straight line formed by two connected vertices with a curve of the inner wall of the groove 202. The groove 202 has a depth and the depth is equal to a projected length of the cross section of the groove 202 along a first direction. The first direction is a direction from a center of the rolling body 201 to a center or a center of gravity of the cross section of the groove 202 along a radial direction.

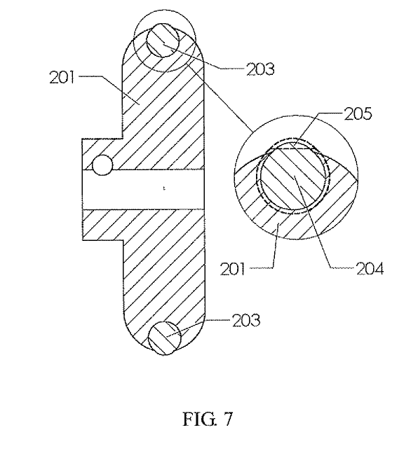

Please refer to FIG. 7, which is a diagram showing a cross section made along B-B′ in FIG. 5. In the present embodiment, the surrounding member 203 has a main portion 204 and a protrusion 205. The protrusion 205 is formed by extending the main portion 204 along the first direction. The first direction is a direction from a center of the rolling body 201 to a center or a center of gravity of the cross section of the groove 202 along a radial direction. The surrounding member 203 has a height and the height is equal to a projected length of the cross section of the surrounding member 203 along the first direction. In the present embodiment, the main portion 204 of the surrounding member 203 has a cross section that is shaped substantially as the same as that of the groove 202 of the rolling body 201. The height of the surrounding member 203 is greater than the depth of the groove 202 in the cross-sectional view. Therefore, the protrusion 205 of the surrounding member 203 can protrude from the outward-curving peripheral surface of the rolling body 201 when the surrounding member 203 and the rolling body 201 are engaged with each other. In the present embodiment, the protrusion 205 and the main body 204 of the surrounding member 203 may be made of the same material. Alternatively, the protrusion 205 and the main body 204 may be made of the different materials. In the process of using the scroll wheel of the present invention to transfer the glass substrate, the protrusion 205 is in contact with the glass substrate and is able to be used to support and transfer the glass substrate. Since the hardness number of the surrounding member 203 of the present invention is lower than that of the glass substrate, the protrusion 205 that directly touches the glass substrate will not make a scratch on the glass substrate.

In the present embodiment, there also has a fastening member (not shown) disposed at the groove 202 of the rolling body 201. Specifically, the fastening member is disposed on an inner wall of the groove 202. The fastening member may be a convex portion and the surrounding member 203 has a concave portion disposed at a position corresponding to the convex portion. The convex portion and the concave portion are engaged with each other. Alternatively, the fastening member may be a concave portion and the surrounding member 203 has a convex portion disposed at a position corresponding to the concave portion. The concave portion and the convex portion are engaged with each other.

Since the scroll wheel of the present invention comprises the rolling body 201 and the surrounding member 203 that are engaged with each other, it only needs to replace the surrounding member 203 rather than replacing the whole wheel when the wheel needs to be maintained or repaired. The rolling body 201 of the present invention can be reused. Therefore, the technical scheme provided in the present invention can reduce the cost. Moreover, the protrusion 205 of the surrounding member 203 that is used to directly in contact with the glass substrate is made of a material with a hardness number lower than that of the glass substrate material. As a result, the scroll wheel will not make a scratch on the glass substrate during the process of using the scroll wheel to transfer the glass substrate. This reduces the damage of the glass substrate. When the surrounding member 203 is required to be replaced, it does not need to take down the rolling body 201. It only needs to detach the surrounding member 203 from the rolling body 201 along its axial direction, and then replace with a new one and engage it with the groove 202 of the rolling body 201 along the axis of the rolling body 201.

Although the present invention has been explained by the embodiments shown in the drawings described above, it should be understood to the ordinary skilled person in the art that the invention is not limited to the embodiments, but rather various changes or modifications thereof are possible without departing from the spirit of the invention. Accordingly, the scope of the invention shall be determined only by the appended claims and their equivalents.

What is claimed is:

1. A scroll wheel for transferring a glass substrate, comprising:
a rolling body having an outward-curving peripheral surface, an outermost circumference on the surface of the rolling body has an groove disposed around, the rolling body rotates on a central axis; and
a surrounding member engaged with the groove of the rolling body, the surrounding member is in contact with the glass substrate and is used to support and transfer the glass substrate, wherein
the surrounding member has a main portion and a protrusion, the protrusion is formed by extending the main portion along a first direction;
the first direction is a direction from a center of the rolling body to a center of a cross section of the groove along a radial direction; and
the main portion of the surrounding member has a cross section that is shaped substantially as the same as that of the groove.

2. The scroll wheel for transferring the glass substrate according to claim 1, wherein the surrounding member has a height greater than a depth of the groove in a cross-sectional view.

3. The scroll wheel for transferring the glass substrate according to claim 2, wherein the height is equal to a projected length of the cross section of the surrounding member along the first direction.

4. The scroll wheel for transferring the glass substrate according to claim 2, wherein the depth is equal to a projected length of the cross section of the groove along the first direction.

5. The scroll wheel for transferring the glass substrate according to claim 1, wherein a hardness number of the surrounding member is lower than that of the glass substrate.

6. A scroll wheel for transferring a glass substrate, comprising:
a rolling body having an outward-curving peripheral surface, an outermost circumference on the surface of the rolling body has an groove disposed around, the rolling body rotates on a central axis; and
a surrounding member engaged with the groove of the rolling body, the surrounding member is in contact with the glass substrate and is used to support and transfer the glass substrate.

7. The scroll wheel for transferring the glass substrate according to claim 6, wherein the surrounding member has a main portion and a protrusion, and the protrusion is formed by extending the main portion along a first direction.

8. The scroll wheel for transferring the glass substrate according to claim 7, wherein the first direction is a direction from a center of the rolling body to a center of a cross section of the groove along a radial direction.

9. The scroll wheel for transferring the glass substrate according to claim 8, wherein the surrounding member has a height greater than a depth of the groove in a cross-sectional view.

10. The scroll wheel for transferring the glass substrate according to claim 9, wherein the depth is equal to a projected length of the cross section of the groove along the first direction.

11. The scroll wheel for transferring the glass substrate according to claim 9, wherein the depth is equal to a projected length of the cross section of the groove along the first direction.

12. The scroll wheel for transferring the glass substrate according to claim 7, wherein the first direction is a direction from a center of the rolling body to a center of gravity of a cross section of the groove along a radial direction.

13. The scroll wheel for transferring the glass substrate according to claim 12, wherein the surrounding member has a height greater than a depth of the groove in a cross-sectional view.

14. The scroll wheel for transferring the glass substrate according to claim 13, wherein the depth is equal to a projected length of the cross section of the groove along the first direction.

15. The scroll wheel for transferring the glass substrate according to claim 13, wherein the depth is equal to a projected length of the cross section of the groove along the first direction.

16. The scroll wheel for transferring the glass substrate according to claim 7, wherein the main portion of the surrounding member has a cross section that is shaped substantially as the same as that of the groove.

17. The scroll wheel for transferring the glass substrate according to claim 6, wherein a hardness number of the surrounding member is lower than that of the glass substrate.

18. The scroll wheel for transferring the glass substrate according to claim 17, wherein the surrounding member is made of rubber.

19. The scroll wheel for transferring the glass substrate according to claim 17, wherein the surrounding member is made of plastic.
